(19) United States
(12) Patent Application Publication
(10) Pub. No.: US 2026/0113833 A1
(43) Pub. Date: Apr. 23, 2026

(54) ELECTRONIC DEVICE AND HEAT DISSIPATION MODULE

(71) Applicant: Wiwynn Corporation, New Taipei City (TW)

(72) Inventors: Po-Sheng Su, New Taipei City (TW); Chun-Yi Sung, New Taipei City (TW); Wei-Ching Chang, New Taipei City (TW)

(73) Assignee: Wiwynn Corporation, New Taipei City (TW)

(21) Appl. No.: 19/086,105

(22) Filed: Mar. 20, 2025

(30) Foreign Application Priority Data
Oct. 22, 2024 (TW) 113140143

(51) Int. Cl. H05K 1/02

(52) U.S. Cl. CPC H05K 1/0203; H05K 2201/064; H05K 2201/066

(57) ABSTRACT

An electronic device includes a heat dissipation module and a circuit board. The heat dissipation module includes a back plate and a first heat dissipation structure. The back plate has an accommodation recess. The first heat dissipation structure is embedded in the accommodation recess. A first side of the circuit board is equipped with a plurality of first electronic components. The circuit board is disposed on the back plate with the first side facing the heat dissipation module, such that the plurality of first electronic components are in contact with the first heat dissipation structure.

### BACKGROUND OF THE INVENTION

### 1. Field of the Invention

The disclosure relates to a heat dissipation module and, more particularly, to a heat dissipation module integrating a heat dissipation structure into a back plate and an electronic device equipped with the heat dissipation module.

### 2. Description of the Prior Art

Heat dissipation is a significant issue for electronic components. When an electronic component is operating, the current in circuit will generate unnecessary heat due to impedance. If the heat is accumulated in the electronic component without dissipating immediately, the electronic component may get damage and/or the performance thereof may get worse due to the accumulated heat. Therefore, how to effectively improve heat dissipating efficiency has become a significant design issue.

### SUMMARY OF THE INVENTION

According to an embodiment of the disclosure, an electronic device comprises a heat dissipation module and a circuit board. The heat dissipation module comprises a back plate and a first heat dissipation structure. The back plate has an accommodation recess. The first heat dissipation structure is embedded in the accommodation recess. A first side of the circuit board is equipped with a plurality of first electronic components. The circuit board is disposed on the back plate with the first side facing the heat dissipation module, such that the plurality of first electronic components are in contact with the first heat dissipation structure.

According to another embodiment of the disclosure, a heat dissipation module comprises a back plate and a first heat dissipation structure. The back plate has an accommodation recess. The first heat dissipation structure is embedded in the accommodation recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic side view illustrating an electronic device according to an embodiment of the disclosure.

FIG. 2 is a perspective view illustrating a heat dissipation module shown in FIG. 1.

FIG. 3 is an exploded view illustrating the heat dissipation module shown in FIG. 2.

FIG. 4 is a schematic side view illustrating the electronic device according to another embodiment of the disclosure.

FIG. 5 is a schematic side view illustrating the electronic device according to another embodiment of the disclosure.

FIG. 6 is a schematic side view illustrating the electronic device according to another embodiment of the disclosure.

FIG. 7 is a schematic side view illustrating the electronic device according to another embodiment of the disclosure.

FIG. 8 is a schematic top view illustrating the heat dissipation module according to another embodiment of the disclosure.

FIG. 9 is a schematic top view illustrating the electronic device according to another embodiment of the disclosure.

### DETAILED DESCRIPTION

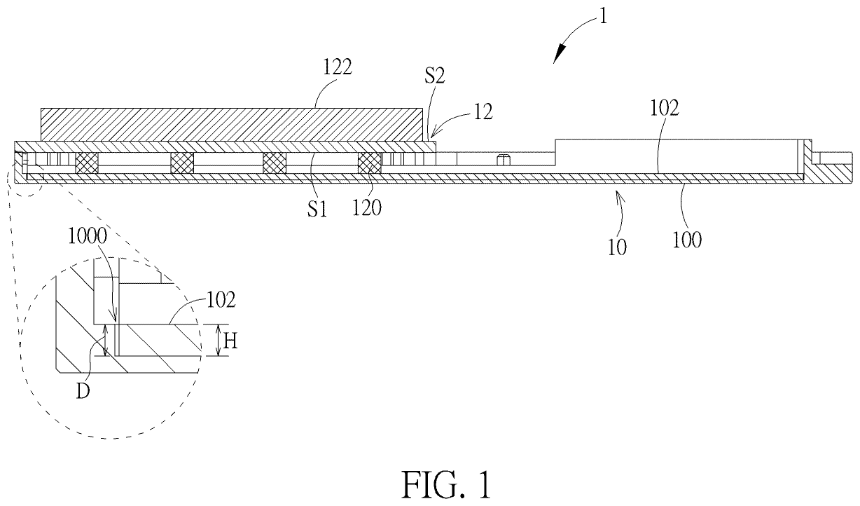

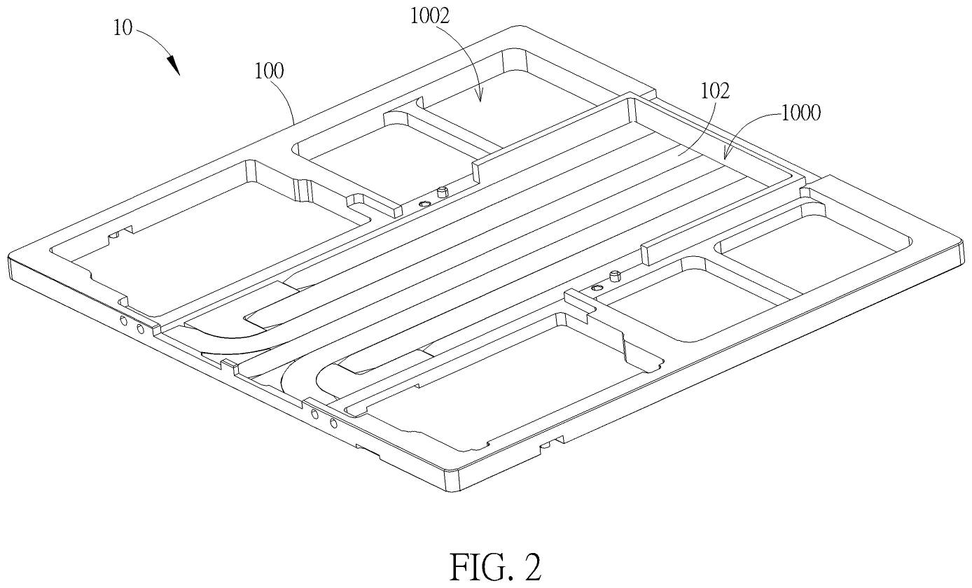

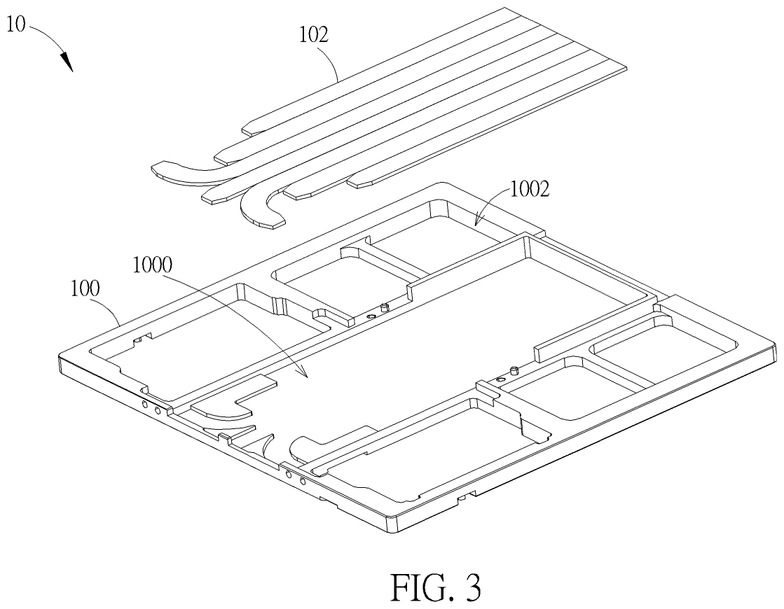

Referring to FIGS. 1 to 3, FIG. 1 is a schematic side view illustrating an electronic device 1 according to an embodiment of the disclosure, FIG. 2 is a perspective view illustrating a heat dissipation module 10 shown in FIG. 1, and FIG. 3 is an exploded view illustrating the heat dissipation module 10 shown in FIG. 2.

As shown in FIG. 1, the electronic device 1 comprises a heat dissipation module 10 and a circuit board 12. A first side S1 of the circuit board 12 is equipped with a plurality of first electronic components 120 and a second side S2 of the circuit board 12 is equipped with a second electronic component 122, wherein the first side S1 is opposite to the second side S2. In this embodiment, the circuit board 12 may be a printed circuit board assembly (PCBA) or the like, the first electronic component 120 may be a voltage regulator (VR) or other electronic components disposed on the circuit board, and the second electronic component 122 may be a central processing unit (CPU), a graphics processing unit (GPU), or the like. The first electronic components 120 disposed on the first side S1 of the circuit board 12 may directly supply power to the second electronic component 122 disposed on the second side S2 of the circuit board 12 through a vertical power delivery (VPD) manner. Accordingly, the space limitation on the second side S2 of the circuit board 12 may be avoided, and the purpose of reducing power loss may be achieved.

As shown in FIGS. 1 to 3, the heat dissipation module 10 comprises a back plate 100 and a first heat dissipation structure 102. The back plate 100 has an accommodation recess 1000. The first heat dissipation structure 102 is embedded in the accommodation recess 1000. In this embodiment, the first heat dissipation structure 102 may comprise a plurality of heat pipes arranged side by side, but the disclosure is not so limited. In this embodiment, a height H of the first heat dissipation structure 102 may be smaller than or equal to a depth D of the accommodation recess 1000, such that the first heat dissipation structure 102 will not protrude from the accommodation recess 1000. By embedding the first heat dissipation structure 102 in the accommodation recess 1000 of the back plate 100, the overall height of the heat dissipation module 10 may be effectively reduced and the design flexibility of the heat dissipation module 10 may be improved. In this embodiment, the back plate 100 may further have at least one hollow region 1002 adjacent to the accommodation recess 1000. The hollow region 1002 may provide avoidance space for the electronic components disposed on the first side S1 of the circuit board 12, so as to prevent the back plate 100 from interfering with the electronic components. It should be noted that the number and position of the hollow region 1002 may be determined according to practical applications, so the disclosure is not limited to the embodiment shown in the figure.

As shown in FIG. 1, the circuit board 12 is disposed on the back plate 100 with the first side S1 facing the heat dissipation module 10, such that the plurality of first electronic components 120 are in contact with the first heat dissipation structure 102. Accordingly, the back plate 100 may be configured to support the circuit board 12 and the first heat dissipation structure 102 may be configured to dissipate heat from the first electronic components 120. By integrating the first heat dissipation structure 102 into the back plate 100, the heat dissipation area may be effectively increased, the contact thermal resistance may be reduced, and the assembly complexity may be reduced.

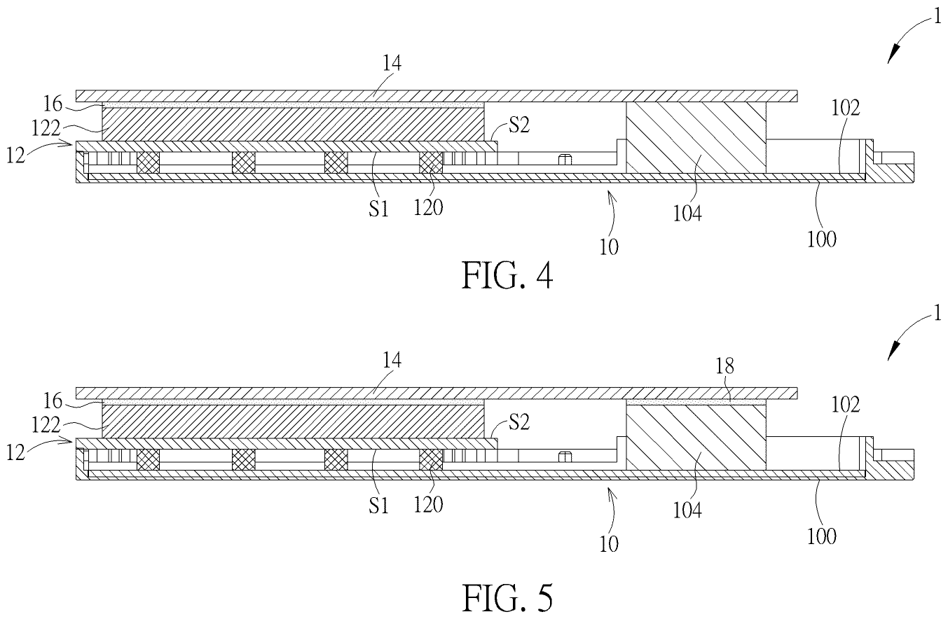

Referring to FIG. 4, FIG. 4 is a schematic side view illustrating the electronic device 1 according to another embodiment of the disclosure.

As shown in FIG. 4, the electronic device 1 may further comprise a second heat dissipation structure 14. The second heat dissipation structure 14 is disposed on the second electronic component 122 and configured to dissipate heat from the second electronic component 122. In this embodiment, the second heat dissipation structure 14 may be a heat sink or a cold plate according to practical applications. It should be noted that the structural design and principle of the heat sink and the cold plate are well known by one skilled in the art, so they will not be depicted in detail herein. Furthermore, the electronic device 1 may further comprise a first thermal interface material 16 sandwiched between the second electronic component 122 and the second heat dissipation structure 14. In this embodiment, the first thermal interface material 16 may be thermal paste or the like. In some embodiments, the first thermal interface material 16 may cover at least a part of a top surface of the second electronic component 122. When the second electronic component 122 is operating, the heat generated by the second electronic component 122 is conducted to the second heat dissipation structure 14 through the first thermal interface material 16.

In this embodiment, the heat dissipation module 10 may further comprise a heat sink 104 disposed on the back plate 100 and located at a side of the circuit board 12. As shown in FIG. 4, a side of the heat sink 104 is in contact with the first heat dissipation structure 102 and another side of the heat sink 104 directly contacts the second heat dissipation structure 14. After the first heat dissipation structure 102 and the second heat dissipation structure 14 respectively absorb the heat of the first electronic components 120 and the second electronic component 122, the heat sink 104 may further dissipate heat from the first heat dissipation structure 102 and the second heat dissipation structure 14, so as to improve the overall heat dissipation efficiency of the heat dissipation module 10.

Referring to FIG. 5, FIG. 5 is a schematic side view illustrating the electronic device 1 according to another embodiment of the disclosure.

As shown in FIG. 5, the electronic device 1 may further comprise a second thermal interface material 18 sandwiched between the heat sink 104 and the second heat dissipation structure 14. In this embodiment, the second thermal interface material 18 may be thermal paste or the like. In some embodiments, the second thermal interface material 18 may cover at least a part of a top surface of the heat sink 104.

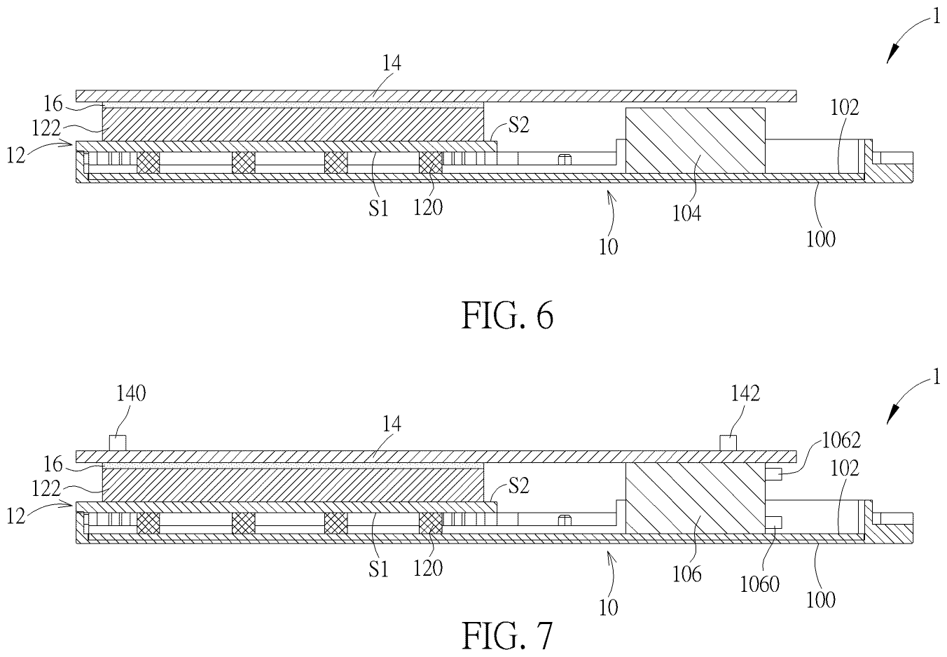

Referring to FIG. 6, FIG. 6 is a schematic side view illustrating the electronic device 1 according to another embodiment of the disclosure.

As shown in FIG. 6, the heat sink 104 may be spaced apart from the second heat dissipation structure 14. In this embodiment, after the first heat dissipation structure 102 absorbs the heat of the first electronic components 120, the heat sink 104 may further dissipate heat from the first heat dissipation structure 102, so as to improve the overall heat dissipation efficiency of the heat dissipation module 10.

Referring to FIG. 7, FIG. 7 is a schematic side view illustrating the electronic device 1 according to another embodiment of the disclosure.

As shown in FIG. 7, the heat dissipation module 10 may further comprise a cold plate 106 disposed on the back plate 100 and located at a side of the circuit board 12. In other words, the aforesaid heat sink 104 may be replaced by the cold plate 106. In this embodiment, the second heat dissipation structure 14 may be another cold plate with an inlet 140 and an outlet 142. Furthermore, the cold plate 106 may have an inlet 1060 and an outlet 1062. The cold plate 106 is in contact with the first heat dissipation structure 102 and communicates with the second heat dissipation structure 14, such that a cooling liquid is able to flow between the cold plate 106 and the second heat dissipation structure 14. The inlets 140, 1060 and the outlets 142, 1062 may be respectively connected to liquid cooling components (not shown) through tubes, so as to form a circulation path for the cooling liquid. After the first heat dissipation structure 102 and the second heat dissipation structure 14 respectively absorb the heat of the first electronic components 120 and the second electronic component 122, the cold plate 106 may further dissipate heat from the first heat dissipation structure 102 and the second heat dissipation structure 14, so as to improve the overall heat dissipation efficiency of the heat dissipation module 10.

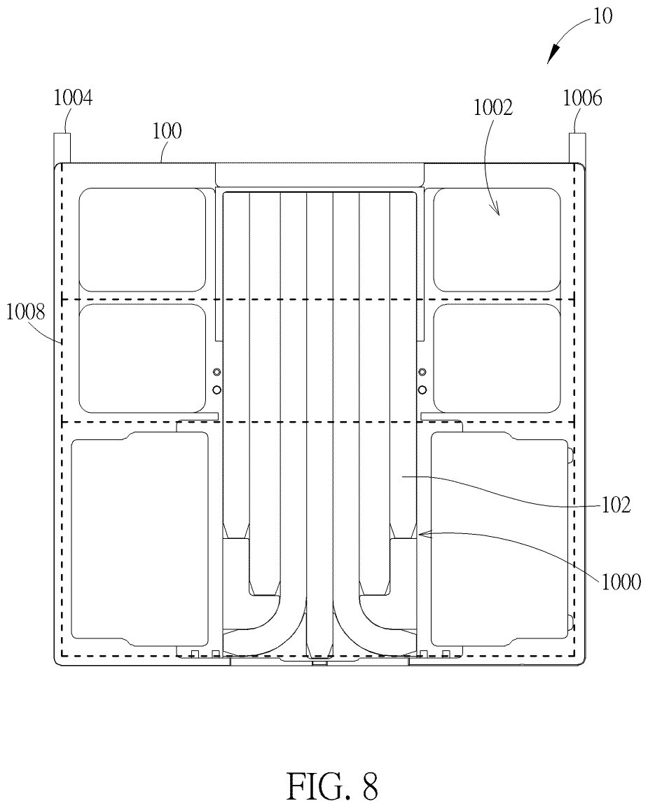

Referring to FIG. 8, FIG. 8 is a schematic top view illustrating the heat dissipation module 10 according to another embodiment of the disclosure.

As shown in FIG. 8, the back plate 100 may further have an inlet 1004, an outlet 1006 and at least one passage 1008, wherein the at least one passage 1008 connects the inlet 1004 and the outlet 1006. It should be noted that the passage 1008 shown in FIG. 8 is illustrated by a dotted line. In practical applications, the at least one passage 1008 may be a structure for the cooling liquid to flow therein. In this embodiment, the at least one passage 1008 may be formed in the back plate 100, such that the at least one passage 1008 passes through a portion of the back plate below the accommodation recess 1000 to be partially located below the first heat dissipation structure 102. Thus, in addition to supporting the circuit board 12, the back plate 100 may also be used as a cold plate, so as to improve the overall heat dissipation efficiency of the heat dissipation module 10.

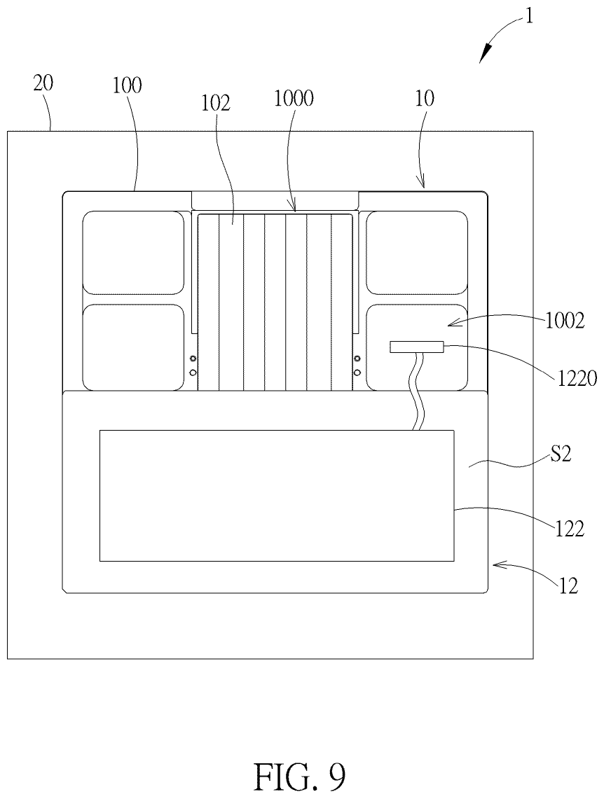

Referring to FIG. 9, FIG. 9 is a schematic top view illustrating the electronic device 1 according to another embodiment of the disclosure.

As shown in FIG. 9, the electronic device 1 may further comprise a substrate 20 (e.g. motherboard). The back plate 100 of the heat dissipation module 10 is disposed on the substrate 20. The second electronic component 122 disposed on the second side S2 of the circuit board 12 may have a connector 1220. The connector 1220 of the second electronic component 122 may pass through the at least one hollow region 1002 to be electrically connected to the substrate 20, such that the second electronic component 122 is electrically connected to the substrate 20.

As mentioned in the above, by integrating the first heat dissipation structure into the back plate, the heat dissipation area may be effectively increased, the contact thermal resistance may be reduced, and the assembly complexity may be reduced. For further explanation, by embedding the first heat dissipation structure in the accommodation recess of the back plate, the overall height of the heat dissipation module may be effectively reduced and the design flexibility of the heat dissipation module may be improved. Furthermore, the heat sink or the cold plate may be disposed on the back plate and in contact with the first heat dissipation structure, so as to improve the overall heat dissipation efficiency of the heat dissipation module. Moreover, in addition to supporting the circuit board, the back plate may also be used as a cold plate, so as to improve the overall heat dissipation efficiency of the heat dissipation module.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a heat dissipation module comprising a back plate and a first heat dissipation structure, the back plate having an accommodation recess, the first heat dissipation structure being embedded in the accommodation recess; and
a circuit board, a first side of the circuit board being equipped with a plurality of first electronic components, the circuit board being disposed on the back plate with the first side facing the heat dissipation module, such that the plurality of first electronic components are in contact with the first heat dissipation structure.

2. The electronic device of claim 1, wherein a second side of the circuit board is equipped with a second electronic component, the first side is opposite to the second side, the electronic device further comprises a second heat dissipation structure, and the second heat dissipation structure is disposed on the second electronic component.

3. The electronic device of claim 2, further comprising a first thermal interface material sandwiched between the second electronic component and the second heat dissipation structure.

4. The electronic device of claim 2, wherein the heat dissipation module further comprises a heat sink disposed on the back plate and located at a side of the circuit board, and a side of the heat sink is in contact with the first heat dissipation structure.

5. The electronic device of claim 4, wherein the heat sink is spaced apart from the second heat dissipation structure.

6. The electronic device of claim 4, wherein the heat sink directly contacts the second heat dissipation structure.

7. The electronic device of claim 4, further comprising a second thermal interface material sandwiched between the heat sink and the second heat dissipation structure.

8. The electronic device of claim 2, wherein the heat dissipation module further comprises a cold plate disposed on the back plate and located at a side of the circuit board, the second heat dissipation structure is another cold plate, the cold plate is in contact with the first heat dissipation structure and communicates with the second heat dissipation structure, such that a cooling liquid is able to flow between the cold plate and the second heat dissipation structure.

9. The electronic device of claim 1, wherein the back plate further has an inlet, an outlet and at least one passage, and the at least one passage connects the inlet and the outlet.

10. The electronic device of claim 9, wherein the at least one passage passes through a portion of the back plate below the accommodation recess to be partially located below the first heat dissipation structure.

11. The electronic device of claim 1, wherein the back plate further has at least one hollow region adjacent to the accommodation recess.

12. The electronic device of claim 11, further comprising a substrate, the back plate being disposed on the substrate, a second side of the circuit board being equipped with a second electronic component, the first side being opposite to the second side, a connector of the second electronic component passing through the at least one hollow region to be electrically connected to the substrate.

13. The electronic device of claim 1, wherein a height of the first heat dissipation structure is smaller than or equal to a depth of the accommodation recess.

14. A heat dissipation module comprising:
a back plate having an accommodation recess; and
a first heat dissipation structure embedded in the accommodation recess.

15. The heat dissipation module of claim 14, further comprising a heat sink or a cold plate disposed on the back plate and in contact with the first heat dissipation structure.

16. The heat dissipation module of claim 14, wherein the back plate further has an inlet, an outlet and at least one passage, and the at least one passage connects the inlet and the outlet.

17. The heat dissipation module of claim 16, wherein the at least one passage passes through a portion of the back plate below the accommodation recess to be partially located below the first heat dissipation structure.

18. The heat dissipation module of claim 14, wherein the back plate further has at least one hollow region adjacent to the accommodation recess.

19. The heat dissipation module of claim 14, wherein a height of the first heat dissipation structure is smaller than or equal to a depth of the accommodation recess.
